(19) United States
(12) Patent Application Publication
(10) Pub. No.: US 2026/0247974 A1
(43) Pub. Date: Aug. 20, 2026

(54) SEMICONDUCTOR DEVICE INCLUDING WARPAGE PREVENTION METAL PATTERNS

(71) Applicant: SK hynix Inc., Icheon-si (KR)

(72) Inventors: Sung Lae OH, Icheon-si (KR); Jae Eun JEON, Icheon-si (KR); Sang Hyun SUNG, Icheon-si (KR)

(21) Appl. No.: 19/261,570

(22) Filed: Jul. 7, 2025

(30) Foreign Application Priority Data
Feb. 20, 2025 (KR) 10-2025-0022381

(51) Int. Cl. H10W 42/00; H10W 20/20; H10W 20/41

(52) U.S. Cl. CPC H10W 42/121; H10W 20/20; H10W 20/427

(57) ABSTRACT

A semiconductor device includes a substrate including a first surface that is defined with an integrated circuit and a second surface that is opposite to the first surface and is defined with a plurality of trenches; a plurality of warpage prevention metal patterns disposed in the plurality of trenches; and a plurality of power lines disposed under the second surface of the substrate and connected to the plurality of warpage prevention metal patterns.

### CROSS-REFERENCE TO RELATED APPLICATION

The present application claims priority under 35 U.S.C. §119(a) to Korean Patent Application No. 10-2025-0022381 filed in the Korean Intellectual Property Office on February 20, 2025, which is incorporated herein by reference in its entirety.

### BACKGROUND

### 1. Technical Field

Embodiments of the present disclosure relate to a semiconductor device.

### 2. Related Art

As the capacity and operating speeds of semiconductor devices increase, current flowing through the power distribution networks (PDN) of semiconductor devices is also gradually increasing. As a result, problems in managing voltage drop in power distribution networks (PDN) are also increasing.

Material layers used in semiconductor manufacturing processes have their own unique stress, and warpage may occur in the semiconductor device due to the stress induced during a material layer deposition process and a heat treatment process.

### SUMMARY

Embodiments of the present disclosure are directed to providing a semiconductor device with improved PDN characteristics and improved warpage characteristics.

The tasks associated with embodiments of the present disclosure are not limited to the tasks mentioned in the present specification, and other tasks not mentioned will be clearly understood by those skilled in the art from the description below.

In an embodiment, a semiconductor device may include: a substrate including a first surface common to an integrated circuit and a second surface that is opposite to the first surface and common to a plurality of trenches; a plurality of warpage prevention metal patterns disposed in the plurality of trenches; and a plurality of power lines disposed under the second surface of the substrate and connected to the plurality of warpage prevention metal patterns.

In an embodiment, a semiconductor device may include: a first structure including a substrate that is defined with a plurality of trenches on a second surface opposite to a first surface defined with a peripheral circuit, a plurality of warpage prevention metal patterns that are disposed in the plurality of trenches, and a plurality of power lines that are disposed under the second surface of the substrate and are connected to the plurality of warpage prevention metal patterns; and a second structure vertically overlapping the first structure and including a memory cell array.

In an embodiment, a semiconductor device may include: a substrate including a first surface that is defined with an integrated circuit, and a second surface that is opposite to the first surface and defined with a trench on the second surface; a warpage prevention metal pattern disposed in the trench; and a power line disposed under the second surface of the substrate and connected to the warpage prevention metal pattern.

According to embodiments of the present disclosure, it is possible to provide a semiconductor device with improved PDN characteristics and suppressed warpage.

Effects of embodiments of the present disclosure are not limited to those mentioned above, and other effects not mentioned will be clearly understood by those skilled in the art from the description of claims.

### BRIEF DESCRIPTION OF THE DRAWINGS

The present disclosure will be more fully understood from the detailed description to be made below and the accompanying drawings, which are provided for illustration only and are not intended to limit the present disclosure.

FIG. 1 is a cross-sectional view illustrating a part of a semiconductor device according to an embodiment of the present disclosure.

FIG. 2 is a plan view of first and second warpage prevention metal patterns of a semiconductor device according to the embodiment of the present disclosure.

FIG. 3 to FIG. 8 are cross-sectional views illustrating various shapes of first warpage prevention metal patterns according to embodiments of the present disclosure.

FIG. 9 to FIG. 11 are cross-sectional views illustrating a method of manufacturing a semiconductor device according to an embodiment of the present disclosure.

FIG. 12 is a cross-sectional view illustrating a part of a semiconductor device according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element in between.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

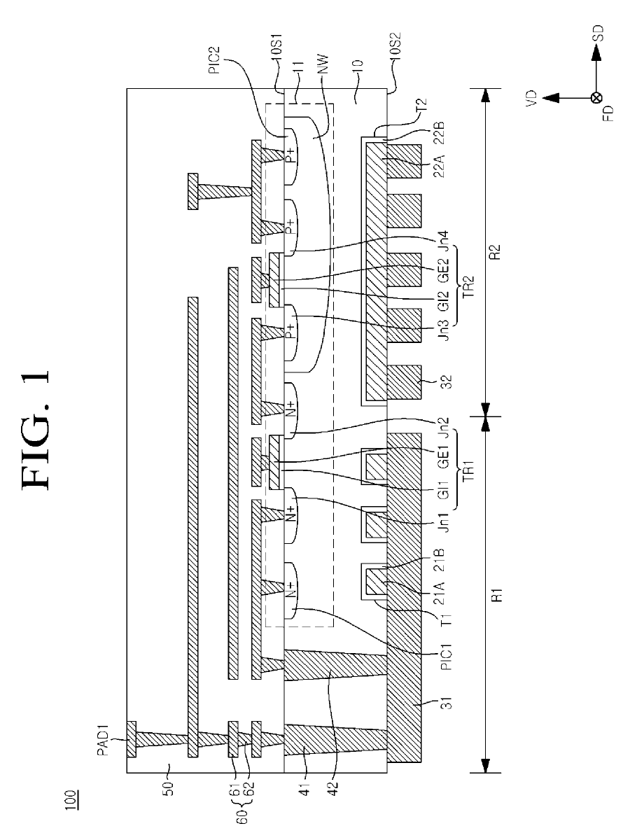

FIG. 1 is a cross-sectional view illustrating a part of a semiconductor device according to an embodiment of the present disclosure.

Referring to FIG. 1, a semiconductor device 100 according to an embodiment of the present disclosure may include a substrate 10, an integrated circuit 11, warpage prevention metal patterns 21A and 22A, and power lines 31 and 32. The semiconductor device 100 may further include through electrodes 41 and 42, a first insulating layer 50, a first wiring structure 60, and a first bonding pad PAD1.

The substrate 10 may include a semiconductor material. The semiconductor material may include silicon (Si), germanium (Ge) or silicon germanium (SiGe). The substrate 10 has a first surface 10S1 and a second surface 10S2 opposite to the first surface 10S1.

The integrated circuit 11 may be disposed on the first surface 10S1 of the substrate 10. The integrated circuit 11 may include a plurality of individual elements. As illustrated in FIG. 1, the individual elements may include transistors TR1 and TR2.

The transistors TR1 and TR2 may include a first transistor TR1 and a second transistor TR2. The first transistor TR1 may include a first gate insulating layer GI1 defined on the substrate 10, a first gate electrode GE1 on the first gate insulating layer GI1, and first and second junction areas Jn1 and Jn2 defined in the substrate 10 and on both sides of the first gate electrode GE1. The second transistor TR2 may be disposed in a well region NW that is defined in the substrate 10. The second transistor TR2 may include a second gate insulating layer GI2 disposed on the well region NW of the substrate 10, a second gate electrode GE2 on the second gate insulating layer GI2, and third and fourth junction areas Jn3 and Jn4 defined in the well region NW and on both sides of the second gate electrode GE2. In an example, the substrate 10 may be a P-type substrate, the well region NW may be an N-well, the first transistor TR1 may be an NMOS transistor, and the second transistor TR2 may be a PMOS transistor.

A first pickup area PIC1 may be formed when an impurity is injected into the substrate 10. A second pickup area PIC2 may be formed when an impurity is injected into the well region NW. The first pickup area PIC1 may be formed as an N-type impurity is injected into the P-type substrate 10, and the second pickup area PIC2 may be formed as a P-type impurity is injected into the N-type well region NW. The first pickup area PIC1 may be connected to the first transistor TR1 and a second through electrode 42 through the first wiring structure 60. The second pickup area PIC2 may be connected to the second transistor TR2 through the first wiring structure 60.

Trenches T1 and T2 may be defined on the second surface 10S2 of the substrate 10. The semiconductor device 100 may include a first region R1 and a second region R2, and the trenches T1 and T2 may include first trenches T1 that are disposed in the first region R1 and a second trench T2 that is disposed in the second region R2.

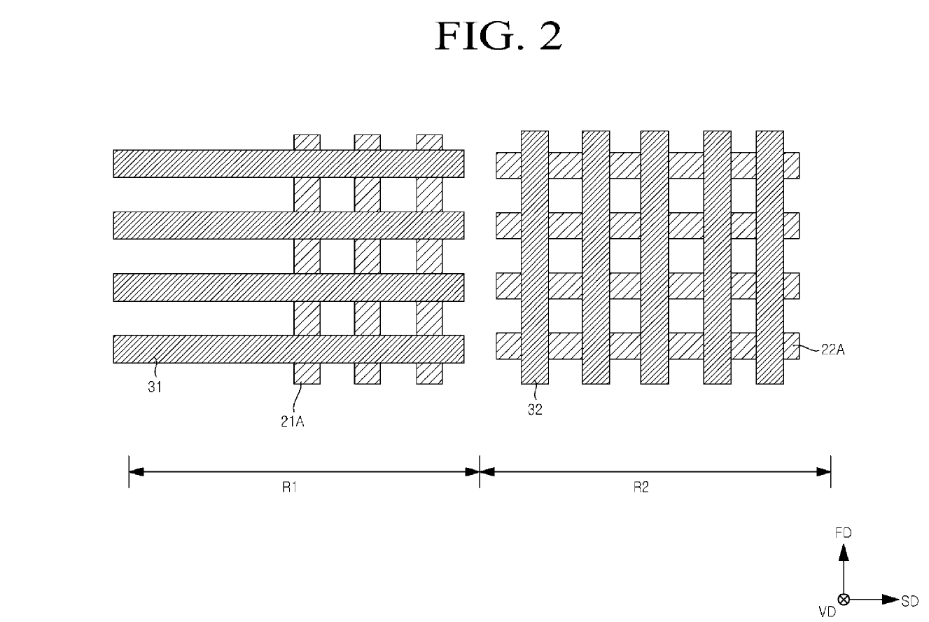

The warpage prevention metal patterns 21A and 22A may include first warpage prevention metal patterns 21A that are disposed in the first trenches T1 and a second warpage prevention metal pattern 22A that is disposed in the second trench T2. Although only one second warpage prevention metal pattern 22A is illustrated in FIG. 1, as will be described later with reference to FIG. 2, a plurality of second warpage prevention metal patterns 22A may be arranged in a first direction FD.

The first and second warpage prevention metal patterns 21A and 22A may include metal having a greater hardness than the substrate 10. For example, when the substrate 10 is formed with silicon, the first and second warpage prevention metal patterns 21A and 22A may include metal having a greater hardness than silicon. The first and second warpage prevention metal patterns 21A and 22A may suppress or prevent warpage of the semiconductor device 100 by adding stiffness.

Each of the first and second warpage prevention metal patterns 21A and 22A may have a solid structure. In an embodiment, each of the first and second warpage prevention metal patterns 21A and 22A may have a rectangular cross-sectional structure.

A first liner insulating layer 21B may be disposed between the first warpage prevention metal pattern 21A and the substrate 10. The first liner insulating layer 21B may cover the surface of the substrate 10 that is exposed by the first trench T1. The first liner insulating layer 21B may isolate the first warpage prevention metal pattern 21A from the substrate 10. The lower surface of the first warpage prevention metal pattern 21A and the lower end surface of the first liner insulating layer 21B may be exposed on the second surface 10S2 of the substrate 10.

A second liner insulating layer 22B may be disposed between the second warpage prevention metal pattern 22A and the substrate 10. The second liner insulating layer 22B may cover the surface of the substrate 10 that is exposed by the second trench T2. The second liner insulating layer 22B may isolate the second warpage prevention metal pattern 22A from the substrate 10. The lower surface of the second warpage prevention metal pattern 22A and the lower end surface of the second liner insulating layer 22B may be exposed on the second surface 10S2 of the substrate 10.

The power lines 31 and 32 may be disposed under the second surface 10S2 of the substrate 10. The power lines 31 and 32 may include metal having a greater hardness than the substrate 10. For example, when the substrate 10 is formed with silicon, the power lines 31 and 32 may include metal having a greater hardness than silicon.

The power lines 31 and 32 may include a first power line 31 that is disposed in the first region R1 and second power lines 32 that are disposed in the second region R2. Although only one first power line 31 is illustrated in FIG. 1, as will be described later with reference to FIG. 2, a plurality of first power lines 31 may be arranged in the first direction FD.

The first insulating layer 50 may be disposed on the first surface 10S1 of the substrate 10, and may cover the integrated circuit 11. The first bonding pad PAD1, as an external contact point of the semiconductor device 100 for electrical connection with an external device, may be disposed on the upper surface of the first insulating layer 50.

The first wiring structure 60 may be disposed within the first insulating layer 50. The first wiring structure 60 may include a plurality of first wirings 61 that are arranged at different vertical levels and a plurality of first vias 62 that extend in a vertical direction VD. The first via 62 may electrically connect first wirings 61 that are disposed at different vertical levels.

First and second through electrodes 41 and 42 may pass through the substrate 10 in the vertical direction VD. The first and second through electrodes 41 and 42 may be electrically connected to the first power line 31. The first and second through electrodes 41 and 42 may electrically connect the first power line 31 and the first wiring structure 60.

The first through electrode 41 may be electrically connected to the first bonding pad PAD1 through the first wiring structure 60. The first bonding pad PAD1 may be electrically connected to the first power line 31 through the first wiring structure 60 and the first through electrode 41. The second through electrode 42 may be electrically connected to the integrated circuit 11 through the first wiring structure 60. The integrated circuit 11 may be electrically connected to the first power line 31 through the first wiring structure 60 and the second through electrode 42.

FIG. 2 is a plan view of first and second warpage prevention metal patterns of a semiconductor device according to the embodiment of the present disclosure.

Referring to FIG. 2, when viewed in a plan view, the first warpage prevention metal patterns 21A and the second warpage prevention metal patterns 22A may have a line shape. The first warpage prevention metal patterns 21A disposed in the first region R1 and the second warpage prevention metal patterns 22A disposed in the second region R2 may extend in different directions. In an embodiment, the first warpage prevention metal patterns 21A and the second warpage prevention metal patterns 22A may extend in parallel to different edges of the substrate. As illustrated in FIG. 2, the first warpage prevention metal patterns 21A may extend in the first direction FD, and the second warpage prevention metal patterns 22A may extend in a second direction SD. Because the warpage prevention metal patterns 21A and 22A extend in different directions in respective regions, it is possible to prevent warping stresses from being concentrated in one direction and to improve stiffness to maintain flat surfaces, thereby reducing warpage from occurring in the semiconductor device 100.

The first power lines 31 and the second power lines 32 may have a line shape. The first power lines 31 disposed in the first region R1 and the second power lines 32 disposed in the second region R2 may extend in different directions. As illustrated in FIG. 2, the first power lines 31 may extend in the second direction SD, and the second power lines 32 may extend in the first direction FD. Because the extending directions of the power lines 31 and 32 are different in respective regions, their arrangement also distributes stress in different directions, thereby suppressing warpage from occurring in the semiconductor device 100.

In the first region R1, the first warpage prevention metal patterns 21A and the first power lines 31 may intersect each other in a plan view. The first power lines 31 may contact the first warpage prevention metal patterns 21A at intersections with the first warpage prevention metal patterns 21A, and may be electrically connected to the first warpage prevention metal patterns 21A.

The first warpage prevention metal patterns 21A and the first power lines 31 may form a mesh structure. In addition, because the first warpage prevention metal patterns 21A and the first power lines 31 have a greater hardness than the substrate 10, warpage may be suppressed from occurring in the semiconductor device 100 by using such mesh structures.

A first voltage may be applied to the first warpage prevention metal patterns 21A and the first power lines 31. The first voltage may be a power supply voltage or a ground voltage. The first warpage prevention metal patterns 21A and the first power lines 31 may form a power mesh.

The second warpage prevention metal patterns 22A and the second power lines 32 may intersect each other in a plan view. The second power lines 32 may contact the second warpage prevention metal patterns 22A at intersections with the second warpage prevention metal patterns 22A, and may be electrically connected to the second warpage prevention metal patterns 22A.

The second warpage prevention metal patterns 22A and the second power lines 32 may form a mesh structure. In addition, because the second warpage prevention metal patterns 22A and the second power lines 32 have a greater hardness than the substrate 10, warpage may be suppressed from occurring in the semiconductor device 100 by using these mesh structures.

The first voltage may be applied to the second warpage prevention metal patterns 22A and the second power lines 32. The first voltage may be a power supply voltage or a ground voltage. The second warpage prevention metal patterns 22A and the second power lines 32 may form a power mesh.

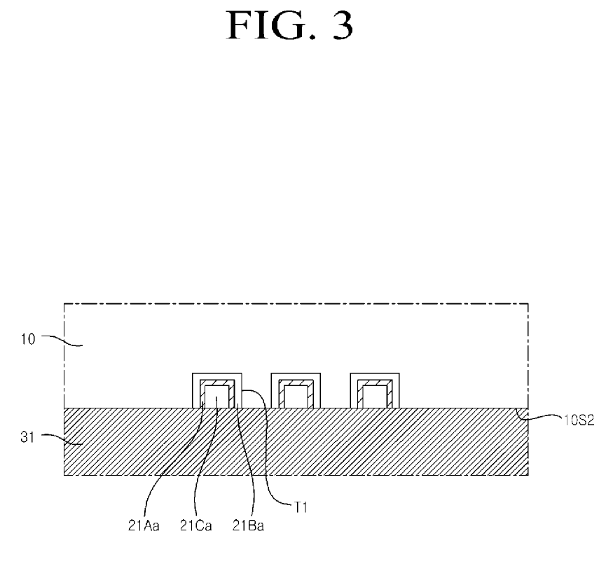

In the embodiments described above with reference to FIG. 1 and FIG. 2, the first and second warpage prevention metal patterns 21A and 22A have a rectangular cross-sectional structure, but the present disclosure is not limited thereto. As will be described hereunder with reference to FIG. 3 to FIG. 8, the cross-sectional structure of the first warpage prevention metal pattern 21A may be changed in various ways. Descriptions of first warpage prevention metal patterns to be made hereunder with reference to FIG. 3 to FIG. 8 may be similarly applied to second warpage prevention metal patterns.

FIG. 3 to FIG. 8 are cross-sectional views illustrating various shapes of first warpage prevention metal patterns according to embodiments of the present disclosure.

Referring to FIG. 3, a first warpage prevention metal pattern 21Aa may have a cross section that is a rectangular half pipe shape or a rectangular half frame shape, which is partly hollow with a concave section with an opening on a second surface 10S2 of a substrate 10.

A first liner insulating layer 21Ba may be disposed between the first warpage prevention metal pattern 21Aa and the substrate 10. The first liner insulating layer 21Ba may cover the surface of the substrate 10 that is exposed by a first trench T1. The first liner insulating layer 21Ba may isolate the first warpage prevention metal pattern 21Aa from the substrate 10.

A core insulating layer 21Ca may fill the concave section of the first warpage prevention metal pattern 21Aa and fill in hollow areas. The core insulating layer 21Ca may have a solid structure and fill in the concavity of the pipe or frame of the first warpage prevention metal pattern 21Aa. The first warpage prevention metal pattern 21Aa may be interposed between the core insulating layer 21Ca and the first liner insulating layer 21Ba. A lower end of the first warpage prevention metal pattern 21Aa, a lower end of the first liner insulating layer 21Ba and a lower surface of the core insulating layer 21Ca may be disposed on substantially the same plane as the second surface 10S2 of the substrate 10.

A first power line 31 may be disposed under the second surface 10S2 of the substrate 10. The first power line 31 may contact the lower end of the first warpage prevention metal pattern 21Aa, and may be electrically connected to the first warpage prevention metal pattern 21Aa.

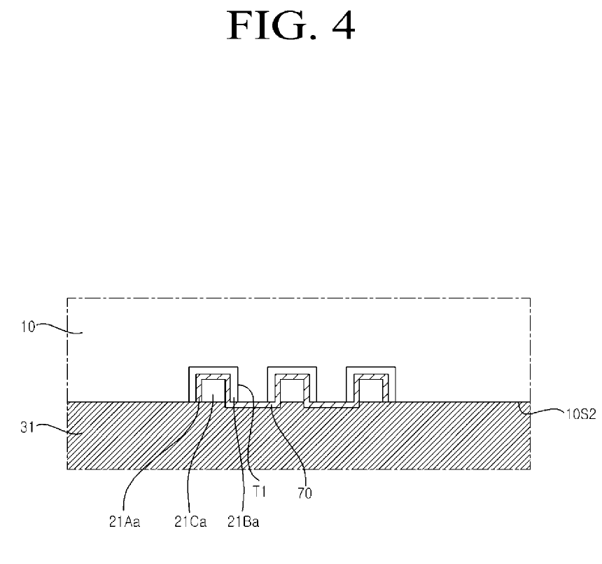

Referring to FIG. 4, a connection line 70 may be disposed on a second surface 10S2 of the substrate 10. The connection line 70 may be formed of a conductive material. The conductive material may include metal. The connection line 70 may be formed of the same material as a first warpage prevention metal pattern 21Aa.

The connection line 70 may be interposed between a portion of a first warpage prevention metal pattern 21Aa and the first power line 31. The connection line 70 may electrically connect a first warpage prevention metal pattern 21Aa and the first power line 31. A first warpage prevention metal pattern 21Aa may be electrically connected to the first power line 31 through the connection line 70. The connection line 70 may connect adjacent first warpage prevention metal patterns 21Aa.

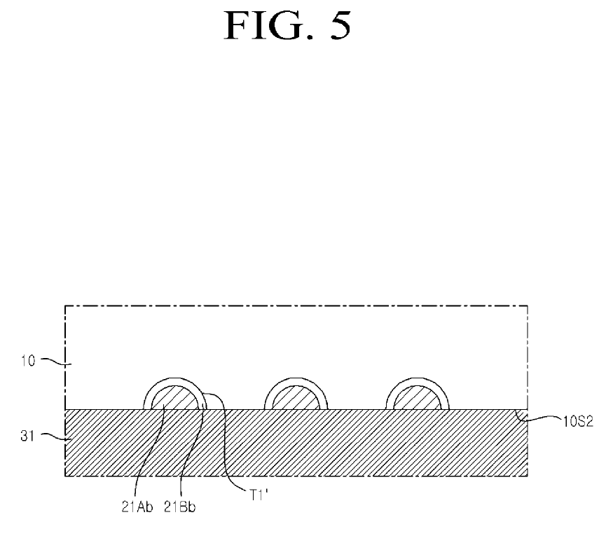

Referring to FIG. 5, a first warpage prevention metal pattern 21Ab may have a semicircular cross-sectional structure.

A first liner insulating layer 21Bb may be disposed between the first warpage prevention metal pattern 21Ab and a substrate 10. The first liner insulating layer 21Bb may cover the surface of the substrate 10 that is exposed by a first trench T1’. The first liner insulating layer 21Bb may isolate the first warpage prevention metal pattern 21Ab from the substrate 10.

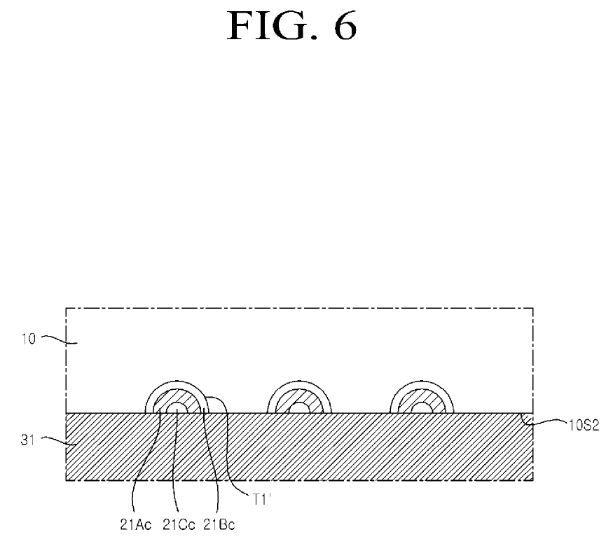

Referring to FIG. 6, a first warpage prevention metal pattern 21Ac may have a half ring-shaped cross-sectional structure. For example, the first warpage prevention metal pattern 21Ac may have a semi-cylindrical pipe shape having a concave section with an opening on the second surface 10S2 of the substrate 10.

A first liner insulating layer 21Bc may be disposed between the first warpage prevention metal pattern 21Ac and the substrate 10. The first liner insulating layer 21Bc may cover the surface of the substrate 10 that is exposed by the first trench T1’. The first liner insulating layer 21Bc may isolate the first warpage prevention metal pattern 21Ac from the substrate 10.

A core insulating layer 21Cc may fill the concave section of the first warpage prevention metal pattern 21Ac and fill in hollow areas. The core insulating layer 21Cc may have a solid structure with a filled central region. The first warpage prevention metal pattern 21Ac may be interposed between the core insulating layer 21Cc and the first liner insulating layer 21Bc.

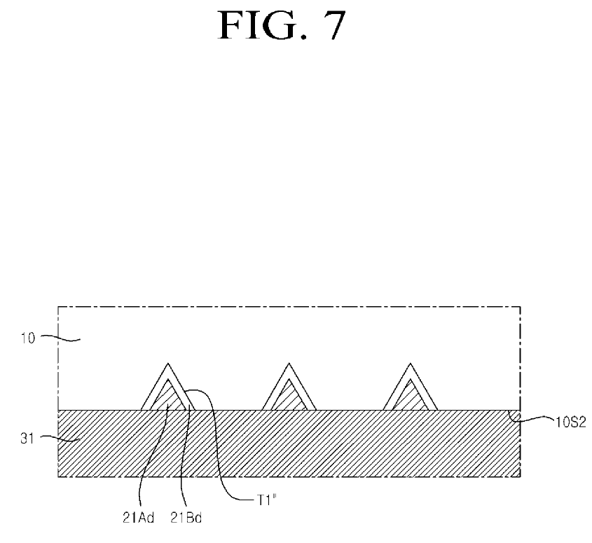

Referring to FIG. 7, a first warpage prevention metal pattern 21Ad may have a tapered cross-sectional structure whose width gradually decreases in an upward direction from its widest width at second surface 10S2 of a substrate 10. The first warpage prevention metal pattern 21Ad may have a triangular cross-sectional structure.

A first liner insulating layer 21Bd may be disposed between the first warpage prevention metal pattern 21Ad and the substrate 10. The first liner insulating layer 21Bd may cover the surface of the substrate 10 exposed by a first trench T1”. The first liner insulating layer 21Bd may isolate the first warpage prevention metal pattern 21Ad from the substrate 10.

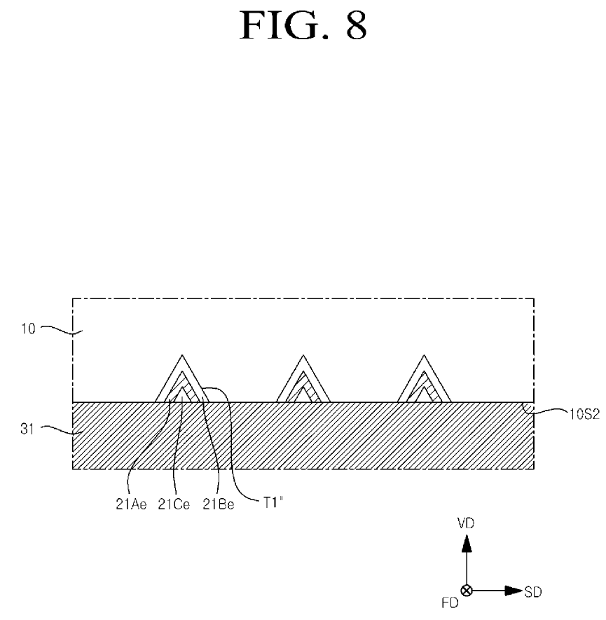

Referring to FIG. 8, a first warpage prevention metal pattern 21Ae may have a tapered half pipe shape whose width gradually decreases in an upward direction from a widest width at a second surface 10S2 of a substrate 10. The first warpage prevention metal pattern 21Ae may have a notched section with an opening on the second surface 10S2 of the substrate 10.

A first liner insulating layer 21Be may be disposed between the first warpage prevention metal pattern 21Ae and the substrate 10. The first liner insulating layer 21Be may cover the surface of the substrate 10 exposed by the first trench T1”, which may have a triangular cross-section. The first liner insulating layer 21Be may isolate the first warpage prevention metal pattern 21Ae from the substrate 10.

A core insulating layer 21Ce may fill in the notched section of the first warpage prevention metal pattern 21Ae. The core insulating layer 21Ce may have a solid structure that fills in the central region of the first warpage prevention metal pattern 21Ae. The first warpage prevention metal pattern 21Ae may be interposed between the core insulating layer 21Ce and the first liner insulating layer 21Be.

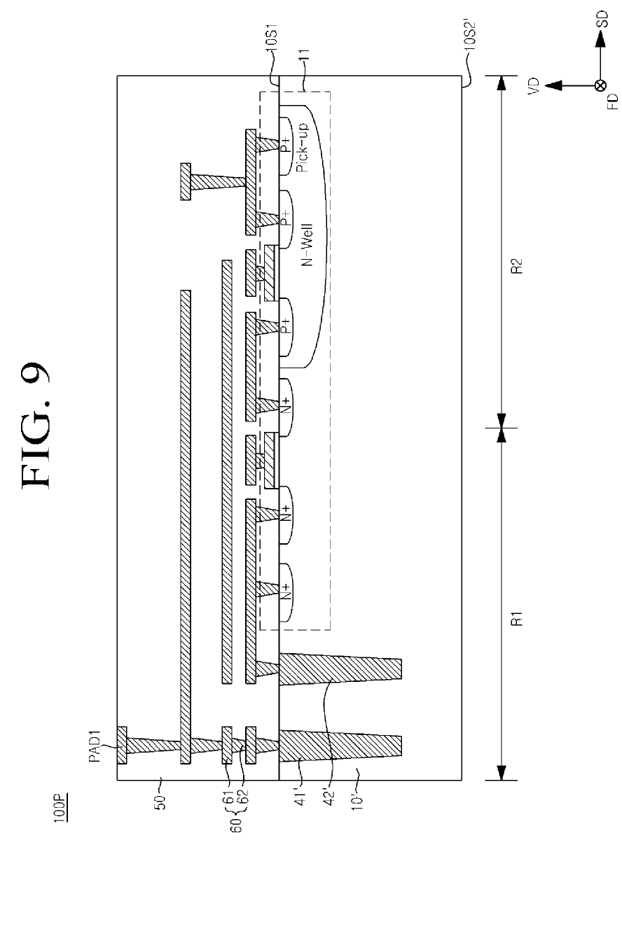

FIG. 9 to FIG. 11 are cross-sectional views illustrating a method of manufacturing a semiconductor device according to an embodiment of the present disclosure.

Referring to FIG. 9, a pre-semiconductor device 100P may be provided.

The pre-semiconductor device 100P may include a substrate 10’, an integrated circuit 11, a first insulating layer 50, first and second through electrodes 41’ and 42’, a first wiring structure 60, and a first bonding pad PAD1.

The substrate 10’ has a first surface 10S1 and a second surface 10S2’ opposite to the first surface 10S1. The integrated circuit 11 may be disposed on the first surface 10S1 of the substrate 10’. The first insulating layer 50 may be disposed on the first surface 10S1 of the substrate 10’, and may cover the integrated circuit 11. The integrated circuit 11 may be connected to the second through electrode 42’ through the first wiring structure 60.

The first and second through electrodes 41’ and 42’ may extend in the vertical direction VD from the first surface 10S1 of the substrate 10’. The upper ends of the first and second through electrodes 41’ and 42’ may be exposed on the first surface 10S1 of the substrate 10’, and the lower ends of the first and second through electrodes 41’ and 42’ may be disposed inside the substrate 10’. The lower ends of the first and second through electrodes 41’ and 42’ do not extend through the substrate 10’ and might not be exposed on the second surface 10S2’ of the substrate 10’.

The first wiring structure 60 may be disposed inside the first insulating layer 50. The first wiring structure 60 may include a plurality of first wirings 61 and a plurality of first vias 62. The first vias 62 may electrically connect first wirings 61 disposed at different vertical levels.

The first bonding pad PAD1 may be disposed on the upper surface of the first insulating layer 50. The first bonding pad PAD1 may be connected to the first through electrode 41’ through the first wiring structure 60.

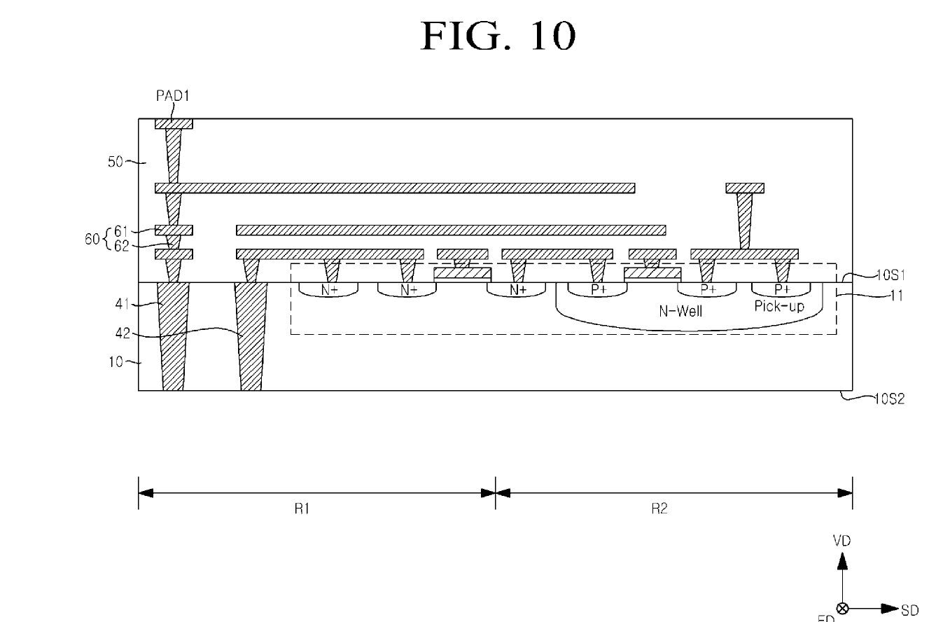

Referring to FIG. 10, the substrate 10’ (see FIG. 9) may be thinned.

In the thinning process, the second surface 10S2' (see FIG. 9) of the substrate 10' (see FIG. 9) may be polished, so that the thickness of the substrate 10' (see FIG. 9) decreases. After the thinning process, the lower ends of first and second through electrodes 41 and 42 may be exposed on a second surface 10S2 of a substrate 10.

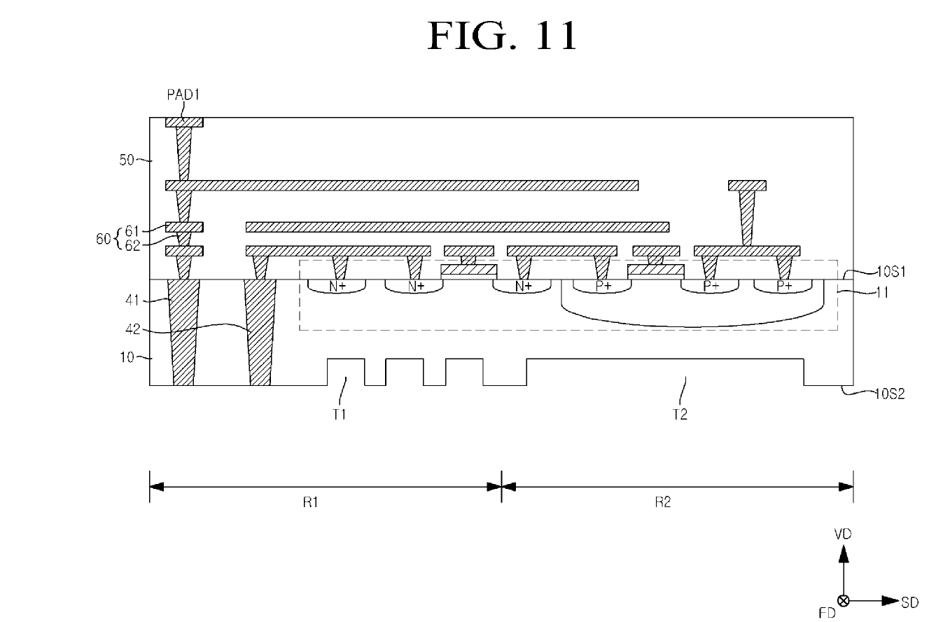

Referring to FIG. 11, trenches T1 and T2 may be formed.

The trenches T1 and T2 may extend from the second surface 10S2 of the substrate 10, and may extend into the substrate 10. The trenches T1 and T2 may include first trenches T1 that are disposed in a first region R1 and a second trench T2 that is disposed in a second region R2. The first trench T1 may have a line shape that extends in the first direction FD. The second trench T2 may have a line shape that extends in the second direction SD. Although only one second trench T2 is illustrated in FIG. 11, a plurality of second trenches T2 may be arranged in the first direction FD.

Referring again to FIG. 1, warpage prevention metal patterns 21A and 22A and power lines 31 and 32 may be formed.

The warpage prevention metal patterns 21A and 22A may include first warpage prevention metal patterns 21A that are disposed in the first trenches T1 and a second warpage prevention metal pattern 22A that is disposed in the second trench T2. The first warpage prevention metal pattern 21A may be formed by filling the first trench T1 with metal. The second warpage prevention metal pattern 22A may be formed by filling the second trench T2 with metal.

The power lines 31 and 32 may include a first power line 31 and second power lines 32. The first power line 31 and the second power lines 32 may have a line shape.

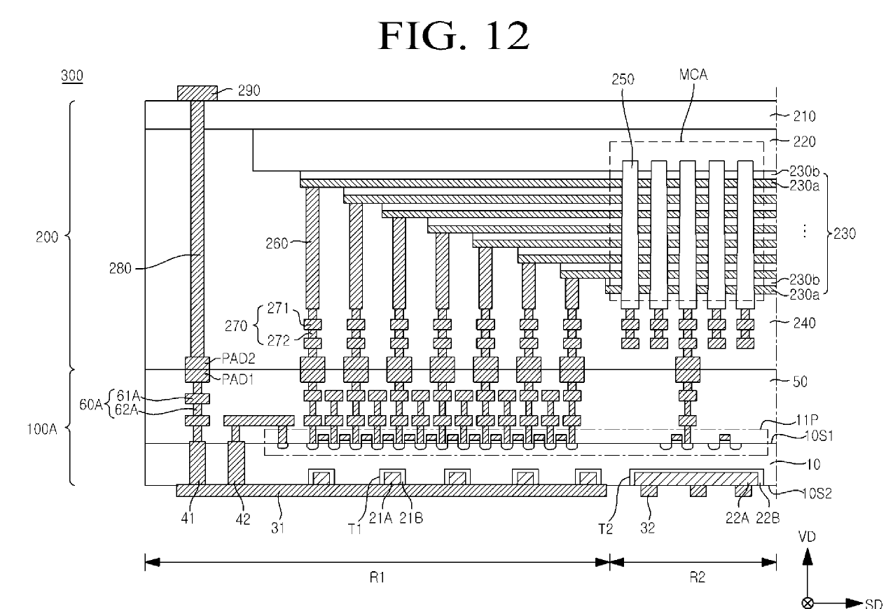

FIG. 12 is a cross-sectional view illustrating a part of a semiconductor device according to an embodiment of the present disclosure.

Referring to FIG. 12, a semiconductor device 300 according to an embodiment of the present disclosure may include a first structure 100A and a second structure 200.

The second structure 200 may be disposed on the first structure 100A. The second structure 200 may include a memory cell array. The memory cell array includes a plurality of memory cells. The memory cell may be a flash memory cell. Although FIG. 12 illustrates a case where the memory cell is a flash memory cell, the type of memory cell is not limited thereto. The memory cell may be any one of a DRAM cell and a resistive memory cell, as non-limiting examples. The first structure 100A may include a peripheral circuit for controlling the memory cell array. The second structure 200 may be a memory structure, and the first structure 100A may be a peripheral circuit structure.

The first structure 100A may include a substrate 10, a peripheral circuit 11P, warpage prevention metal patterns 21A and 22A, power lines 31 and 32, first and second through electrodes 41 and 42, a first insulating layer 50, a first wiring structure 60A, and a first bonding pad PAD1.

The substrate 10 may include a semiconductor material. The semiconductor material may include silicon (Si), germanium (Ge) or silicon germanium (SiGe). The substrate 10 has a first surface 10S1 and a second surface 10S2 opposite to the first surface 10S1.

The peripheral circuit 11P may be disposed on the first surface 10S1 of the substrate 10. The peripheral circuit 11P may include, for example, a row decoder, a page buffer circuit, a control logic and a voltage generator, but is not limited to the elements listed here.

Trenches T1 and T2 may be defined on the second surface 10S2 of the substrate 10. The trenches T1 and T2 may include first trenches T1 that are disposed in a first region R1 of the semiconductor device 300 and a second trench T2 that is disposed in a second region R2 of the semiconductor device 300.

The warpage prevention metal patterns 21A and 22A may be disposed in the trenches T1 and T2. The warpage prevention metal patterns 21A and 22A may include first warpage prevention metal patterns 21A that are disposed in the first trenches T1 and a second warpage prevention metal pattern 22A that is disposed in the second trench T2. A first liner insulating layer 21B may be disposed between the first warpage prevention metal pattern 21A and the substrate 10. The first liner insulating layer 21B may cover the surface of the substrate 10 that is exposed by the first trench T1. A second liner insulating layer 22B may be disposed between the second warpage prevention metal pattern 22A and the substrate 10. The second liner insulating layer 22B may cover the surface of the substrate 10 that is exposed by the second trench T2.

The first and second warpage prevention metal patterns 21A and 22A may include a material having a hardness greater than the hardness of the substrate 10. The first and second warpage prevention metal patterns 21A and 22A may add stiffness and suppress or prevent warpage of the semiconductor device 300.

Although FIG. 12 illustrates first and second warpage prevention metal patterns 21A and 22A as having substantially the same structures as the first and second warpage prevention metal patterns 21A and 22A of FIG. 1, the present disclosure is not limited thereto. A cross-section of a first warpage prevention metal pattern may have the same structure as a first warpage prevention metal pattern described above with reference to any one of FIG. 3 to FIG. 8, and a second warpage prevention metal pattern may have the same structure as a structure that is obtained as a first warpage prevention metal pattern described above with reference to any one of FIG. 3 to FIG. 8, as rotated by 90 degrees in FIG. 12.

The first warpage prevention metal pattern 21A disposed in the first region R1 and the second warpage prevention metal pattern 22A disposed in the second region R2 may extend in different directions. As illustrated in FIG. 12, the first warpage prevention metal pattern 21A may extend in the first direction FD, and the second warpage prevention metal pattern 22A may extend in the second direction SD.

The power lines 31 and 32 are disposed under the second surface 10S2 of the substrate 10. The power lines 31 and 32 may include metal having a hardness greater than the hardness of the substrate 10. For example, when the substrate 10 is formed of silicon, the power lines 31 and 32 may be formed of metal having a greater hardness than silicon.

The power lines 31 and 32 may include, respectively, a first power line 31 that is disposed in the first region R1 and second power lines 32 that are disposed in the second region R2. The first power line 31 disposed in the first region R1 and the second power line 32 disposed in the second region R2 may extend in different directions. As illustrated in FIG. 12, the first power line 31 may extend in the second direction SD, and the second power line 32 may extend in the first direction FD.

In the first region R1, the first warpage prevention metal patterns 21A and the first power line 31 may intersect each other. The first power line 31 may contact the first warpage prevention metal patterns 21A at intersections with the first warpage prevention metal patterns 21A, and may be electrically connected to the first warpage prevention metal patterns 21A.

From a plan view, a mesh structure may be formed by the first warpage prevention metal patterns 21A and the first power line 31. Because the mesh structure is formed by the first warpage prevention metal patterns 21A and the first power line 31, both having a hardness greater than the substrate 10, warpage may be suppressed from occurring in the semiconductor device 300.

A first voltage may be loaded to the first warpage prevention metal patterns 21A and a plurality of first power lines 31. The first voltage may include a power supply voltage or a ground voltage. The first warpage prevention metal patterns 21A and the first power line 31 may form a power mesh.

In the second region R2, the second warpage prevention metal pattern 22A and the second power lines 32 may intersect each other. The second power lines 32 may contact the second warpage prevention metal pattern 22A at intersections with the second warpage prevention metal pattern 22A. The second power lines 32 may be electrically connected to the second warpage prevention metal pattern 22A.

In a plan view, a mesh structure may be formed by the second warpage prevention metal pattern 22A and the second power lines 32. Because the mesh structure is formed by the second warpage prevention metal pattern 22A and the second power lines 32, both having a hardness greater than the substrate 10, warpage may be suppressed from occurring in the semiconductor device 300.

The first voltage may be loaded to the second warpage prevention metal pattern 22A and the second power lines 32. The first voltage may include a power supply voltage or a ground voltage. The second warpage prevention metal pattern 22A and the second power lines 32 may form a power mesh.

The first insulating layer 50 may be disposed on the substrate 10 and cover the peripheral circuit 11P. The first bonding pad PAD1 may be exposed on the upper surface of the first insulating layer 50. The first wiring structure 60A may be disposed inside the first insulating layer 50. The first wiring structure 60A may include a plurality of first wirings 61A and a plurality of first vias 62A that are disposed in the first insulating layer 50.

The first and second through electrodes 41 and 42 may pass through the substrate 10 in the vertical direction VD. The first and second through electrodes 41 and 42 may be electrically connected to the first power line 31. The first and second through electrodes 41 and 42 may connect the first power line 31 and the first wiring structure 60. The upper surfaces of first bonding pads PAD1 and the upper surface of the first insulating layer 50 may form the upper surface of the first structure 100A.

The second structure 200 may include a second insulating layer 210, a source plate 220, a gate stack 230, a third insulating layer 240, a cell plug 250, a contact 260, a second wiring structure 270, a through via 280, and a second bonding pad PAD2.

The source plate 220 may disposed under the second insulating layer 210. The source plate 220 may include polysilicon. The gate stack 230 may include a plurality of gate electrode layers 230a and a plurality of interlayer insulating layers 230b that are alternately stacked under the source plate 220. The gate electrode layers 230a may include a conductive material. The gate electrode layers 230a may include tungsten (W). The interlayer insulating layers 230b may include silicon oxide.

The gate electrode layers 230a may include word lines. The gate electrode layers 230a may further include at least one source select line and at least one drain select line. The gate electrode layers 230a extend by different lengths to form a stairway structure.

The third insulating layer 240 may cover the source plate 220 and the gate stack 230 under the second insulating layer 210. Contacts 260 may be connected to the stairway structure of the gate electrode layers 230a. The contacts 260 may extend in the vertical direction VD in the third insulating layer 240.

A plurality of cell plugs 250 may extend through the gate stack 230 into the source plate 220 in the vertical direction VD. Each of the cell plugs 250 may include a channel layer and a cell gate insulating layer. The cell gate insulating layer may have a straw or cylindrical shell shape that surrounds the outer wall of the channel layer. The cell gate insulating layer may include a tunnel insulating layer, a charge storage layer and a blocking layer that are sequentially stacked from the outer wall of the channel layer. In some embodiments, the cell gate insulating layer may have an ONO (oxide-nitride-oxide) stack structure in which an oxide layer, a nitride layer and an oxide layer are sequentially stacked. Memory cells may be configured in areas where word lines surround a cell plug 250. A source select transistor may be configured in an area where a source select line surrounds the cell plug 250. A drain select transistor may be configured in an area where a drain select line surrounds the cell plug 250. A drain select transistor, a plurality of memory cells and a source select transistor that are disposed along one cell plug 250 may constitute one cell string. A plurality of cell strings corresponding to the plurality of cell plugs 250 may be defined. The plurality of cell strings may constitute a memory cell array MCA.

The second wiring structure 270 may include a plurality of second wirings 271 that are disposed at different vertical levels in the third insulating layer 240 and a plurality of second vias 272 that extend in the vertical direction VD in the third insulating layer 240.

The second bonding pad PAD2 may be disposed on the lower surface of the third insulating layer 240. The lower surfaces of second bonding pads PAD2 and the lower surface of the third insulating layer 240 may form the lower surface of the second structure 200. Each of the contact 260 and the cell plug 250 may be connected to a corresponding second bonding pad PAD2 through the second wiring structure 270.

The second structure 200 may further include an external connection pad 290 that is disposed on the second insulating layer 210. The external connection pad 290 may be connected to the second bonding pad PAD2 through the through via 280. The through via 280 may pass through the second and third insulating layers 210 and 240 in the vertical direction VD and electrically connect the external connection pad 290 and the second bonding pad PAD2.

The upper surface of the first structure 100A and the lower surface of the second structure 200 may be bonded together. The upper surface of the first bonding pad PAD1 and the lower surface of the second bonding pad PAD2 may be bonded to each other, and the upper surface of the first insulating layer 50 and the lower surface of the third insulating layer 240 may be bonded to each other.

Although, in FIG. 12, the semiconductor device 300 includes one memory structure and one peripheral circuit structure, the present disclosure is not limited thereto. As another example, a semiconductor device may include two or more memory structures, or may include two or more peripheral circuit structures. As still another example, at least one of semiconductor devices included in a semiconductor device may have a PUC (peripheral under cell) structure including a peripheral circuit region and a memory cell region built up on the peripheral circuit region.

According to embodiments of the present disclosure, warpage of a semiconductor device may be suppressed by disposing warpage prevention metal patterns in trenches defined on the second surface of a substrate and forming a mesh structure with the warpage prevention metal patterns and power lines disposed under the second surface of the substrate. By forming a power mesh with the warpage prevention metal patterns and the power lines, the level of power supply voltage or ground voltage may be stabilized and PDN (power distribution network) characteristics may be improved.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor device comprising:
a substrate including a first surface common to an integrated circuit and a second surface that is opposite to the first surface and common to a plurality of trenches;
a plurality of warpage prevention metal patterns disposed in the plurality of trenches; and
a plurality of power lines disposed under the second surface of the substrate and connected to the plurality of warpage prevention metal patterns.

2. The semiconductor device according to claim 1, wherein the plurality of warpage prevention metal patterns and the plurality of power lines form a power mesh.

3. The semiconductor device according to claim 1, further comprising
a through electrode passing through the substrate and connecting one of the plurality of power lines and the integrated circuit.

4. The semiconductor device according to claim 1, wherein the plurality of warpage prevention metal patterns fills the plurality of trenches respectively.

5. The semiconductor device according to claim 4, wherein the plurality of warpage prevention metal patterns has a concave cross-sectional structure or a cross-sectional structure that tapers from a widest width at the second surface of the substrate.

6. The semiconductor device according to claim 4, further comprising
a liner insulating layer between each of the plurality of warpage prevention metal patterns and the substrate.

7. The semiconductor device according to claim 1, wherein each of the plurality of warpage prevention metal patterns has a half pipe shape with a concave section.

8. The semiconductor device according to claim 7, wherein each of the plurality of warpage prevention metal patterns has a rectangular half pipe shape or a semi-cylindrical pipe shape or has a tapered half pipe shape whose width decreases in a direction away from the second surface of the substrate.

9. The semiconductor device according to claim 7, further comprising:
a core insulating layer filling the concave section of one of the plurality of warpage prevention metal patterns; and
a liner insulating layer between the one of the plurality of warpage prevention metal patterns and the substrate.

10. The semiconductor device according to claim 7, further comprising
a connection line disposed common to the second surface of the substrate and connecting one of the plurality of warpage prevention metal patterns and one of the plurality of power lines.

11. The semiconductor device according to claim 10, wherein the connection line connects adjacent warpage prevention metal patterns from among the plurality of warpage prevention metal patterns.

12. The semiconductor device according to claim 1, wherein a ground voltage or a power supply voltage is applied to the plurality of power lines and the plurality of warpage prevention metal patterns.

13. The semiconductor device according to claim 1, wherein the plurality of warpage prevention metal patterns include metal having a hardness greater than the hardness of the substrate.

14. The semiconductor device according to claim 1, wherein the power lines include metal having a hardness greater than the hardness of the substrate.

15. The semiconductor device according to claim 1, wherein the plurality of warpage prevention metal patterns comprise:
a first warpage prevention metal pattern disposed in a first region; and
a second warpage prevention metal pattern disposed in a second region,
wherein an extending direction of the first warpage prevention metal pattern and an extending direction of the second warpage prevention metal pattern are different from each other.

16. The semiconductor device according to claim 15, wherein the plurality of power lines comprise:
a first power line intersecting the first warpage prevention metal pattern; and
a second power line intersecting the second warpage prevention metal pattern,
wherein an extending direction of the first power line and an extending direction of the second power line are different from each other.

17. A semiconductor device comprising:
a first structure including a substrate that is defined with a plurality of trenches on a second surface opposite to a first surface defined with a peripheral circuit, a plurality of warpage prevention metal patterns that are disposed in the plurality of trenches, and a plurality of power lines that are disposed under the second surface of the substrate and are connected to the plurality of warpage prevention metal patterns; and
a second structure vertically overlapping the first structure and including a memory cell array.

18. The semiconductor device according to claim 17, wherein the plurality of warpage prevention metal patterns and the plurality of power lines intersect each other and are electrically connected to each other at intersections.

19. The semiconductor device according to claim 17, further comprising
a through electrode passing through the substrate and connecting one of the plurality of power lines and the peripheral circuit.

20. A semiconductor device comprising:
a substrate including a first surface that is defined with an integrated circuit, and a second surface that is opposite to the first surface and defined with a trench on the second surface;
a warpage prevention metal pattern disposed in the trench; and
a power line disposed under the second surface of the substrate and connected to the warpage prevention metal pattern.
